(19) United States
(12) Patent Application Publication
(10) Pub. No.: US 2016/0027904 A1
(43) Pub. Date: Jan. 28, 2016

(54) METHOD FOR MANUFACTURING COPLANAR OXIDE SEMICONDUCTOR TFT SUBSTRATE

(71) Applicant: Shenzhen China Star Optoelectronics Technology Co. Ltd., Shenzhen, Guangdong (CN)

(72) Inventors: Xiaowen LV, Shenzhen, Guangdong (CN); Chihyuan TSENG, Shenzhen, Guangdong (CN); Chihyu SU, Shenzhen, Guangdong (CN); Yutong HU, Shenzhen, Guangdong (CN); Wenhui LI, Shenzhen, Guangdong (US); Longqiang SHI, Shenzhen, Guangdong (CN); Hejing ZHANG, Shenzhen, Guangdong (CN)

(73) Assignee: Shenzhen China Star Optoelectronics Technology Co. Ltd., Shenzhen, Guangdong (CN)

(21) Appl. No.: 14/382,303

(22) PCT Filed: Aug. 15, 2014
(86) PCT No.: PCT/CN2014/084445

§ 371 Date: Aug. 29, 2014

(30) Foreign Application Priority Data
Jul. 22, 2014 (CN) 201410351501.4

(51) Int. Cl. H01L 29/66; H01L 29/423; H01L 21/02; H01L 21/443; H01L 29/24; H01L 29/786; H01L 21/4757

(52) U.S. Cl. CPC H01L 29/66969; H01L 29/7869; H01L 29/42384; H01L 21/47573; H01L 21/443; H01L 29/24; H01L 21/02565

(57) ABSTRACT

The present invention provides a method for manufacturing a coplanar oxide semiconductor TFT substrate, which includes: step 1: providing a substrate (1); step 2: forming a gate terminal (2); step 3: depositing a gate insulation layer (3); step 4: forming a photoresist layer (4) on the gate insulation layer (3); step 5: subjecting the photoresist layer (4) to sectionized exposure and development to form a through hole (41) and a plurality of recesses (42); step 6: removing a portion of the gate insulation layer (3) under the through hole (41); step 7: removing portions of the photoresist layer (4) under the plurality of recesses (42) of the photoresist layer (4); step 8: depositing a second metal layer (5) on the gate insulation layer (3) and a remaining photoresist layer (4′); step 9: removing the remaining photoresist layer (4′) and a portion of the second metal layer (5) deposited thereon to form source/drain terminals (51); Step 10: depositing and patternizing an oxide semiconductor layer (6); and step 11: depositing and patternizing a protection layer (7).

### BACKGROUND OF THE INVENTION

1. Field of the Invention

The present invention relates to the field of displaying technology, and in particular to a method for manufacturing a coplanar oxide semiconductor TFT (Thin-Film Transistor) substrate.

2. The Related Arts

Flat panel displays have a variety of advantages, such as thin device body, low power consumption, and being free of radiation, and are thus widely used. Currently available flat panel displays generally include liquid crystal displays (LCDs) and organic light emitting displays (OLEDs).

The organic light emitting displays possess excellent advantages of being self-luminous, requiring no backlighting, having a high contrast, a reduced thickness, a wide view angle, and a fast response, being applicable to flexible panels, having a wide range of operation temperature, and having a simple structure and an easy manufacturing process, and are considered an emerging application technique of the next-generation display devices.

In the manufacture of large-sized OLEDs, oxide semiconductors have a relatively high electron mobility and, compared to low-temperature poly-silicon (LTPS), the oxide semiconductors have a simple manufacturing process and have high compatibility with amorphous silicon manufacturing processes and are also compatible with high-generation manufacturing lines so as to be of wide applications.

Currently, a commonly used structure of an oxide semiconductor TFT substrate is a structure comprising an etch stop layer (ESL). Such a structure, however, has certain problems, such as being hard to control etching homogeneity, requiring one additional masking and photolithographic process, overlapping between gate terminal and source/drain terminals, storage capacitance being large, and being hard to achieve high resolution.

Compared to the structure comprising an etch stop layer, a coplanar oxide semiconductor TFT substrate structure seems more reasonable and has a prosperous future for mass production. A conventional way of manufacturing a coplanar oxide semiconductor TFT substrate is illustrated in FIGS. 1-5 and comprises the following steps:

Step 1: depositing a first metal layer on a substrate 100 and applying a photolithographic process to patternize the first metal layer to form a gate terminal 200;

Step 2: depositing a gate insulation layer 300 on the substrate 100 and the gate terminal 200, followed by patternizing through a photolithographic process;

Step 3: depositing a second metal layer on the gate insulation layer 300 and applying a photolithographic process to patternize the second metal layer to form source/drain terminals 400;

Step 4: depositing and patterning through application of a photolithographic process on the source/drain terminals 400 to form an oxide semiconductor layer 500; and

Step 5: depositing and patterning through application of a photolithographic process on the oxide semiconductor layer 500 and the source/drain terminals 400 to form a protection layer 600.

This method for manufacturing the coplanar oxide semiconductor TFT substrate suffers certain drawbacks, which are generally exhibited as that the formation of each layer of the gate terminal 200, the gate insulation layer 300, the source/drain terminals 400, the oxide semiconductor layer 500, and the protection layer 600 requires the application of one photolithographic process and each of the photolithographic processes includes steps of film formation, yellow light, etching, and stripping, of which the yellow light step further comprises coating photoresist, exposure, and development, and each yellow light step needs a mask so that the work flow of the manufacturing process is extended and the manufacturing performance is relatively low; the number of masks used is relatively large and the manufacturing cost is raised; and the increased manufacturing steps make the accumulation of problems of yield rate more prominent.

### SUMMARY OF THE INVENTION

An object of the present invention is to provide a method for manufacturing a coplanar oxide semiconductor TFT (Thin-Film Transistor) substrate so that through such a method, yellow light processes are reduced, workflow of the manufacturing process and production cycle of products are shortened, production efficiency and product yield rate are heightened, competition power of products is enhanced, the number of masks used is reduced, and manufacturing cost is lowered.

To achieve the above object, the present invention provides a method for manufacturing a coplanar oxide semiconductor TFT substrate, which comprises the following steps:

(1) providing a substrate;

(2) depositing and patternizing a first metal layer on the substrate to form a gate terminal;

(3) depositing a gate insulation layer on the gate terminal and the substrate to have the gate insulation layer completely cover the gate terminal and the substrate;

(4) forming a photoresist layer of a predetermined thickness on the gate insulation layer;

(5) subjecting the photoresist layer to sectionized exposure and development;

wherein full exposure and development are performed on an area of the photoresist layer that corresponds to a connection hole to be formed in the gate insulation layer so as to form a through hole; half exposure and development are performed on areas of the photoresist layer that corresponds to source/drain terminals to be formed so as to form a plurality of recesses; and no exposure is performed on a remaining area of the photoresist layer;

(6) applying etching to remove a portion of the gate insulation layer that is under the through hole so as to form a connection hole in the gate insulation layer for exposing a portion of the gate terminal that is under the connection hole;

(7) removing portions of the photoresist layer that are under the plurality of recesses of the photoresist layer for exposing portions of the gate insulation layer that are under the plurality of recesses;

(8) depositing a second metal layer on the gate insulation layer and a remaining photoresist layer in such a way that the second metal layer is filled in the connection hole to connect with the gate terminal;

(9) removing the remaining photoresist layer and portions of the second metal layer deposited thereon so as to form source/drain terminals;

(10) depositing and patternizing an oxide semiconductor layer on the source/drain terminals and the gate insulation layer; and

(11) depositing and patternizing a protection layer on the oxide semiconductor layer and the source/drain terminals.

Patternizing is achieved through photolithography.

In Step (5), a half-tone process is applied to perform the sectionized exposure of the photoresist layer.

In Step (5), the recesses of the photoresist layer have a depth H that is greater than a thickness of the source/drain terminals to be formed.

In Step (6), dry etching is applied to remove the portion of the gate insulation layer that is located under the through hole.

In Step (7), O₂ ashing is applied to remove the portions of the photoresist layer that are located under the plurality of recesses of the photoresist layer.

In Step (8), physical vapor deposition is applied to deposit the second metal layer on the gate insulation layer and the remaining photoresist layer.

In Step (9), a stripping solution is applied to strip and remove the remaining photoresist layer and a portion of the second metal layer deposited thereon in order to form the source/drain terminals.

In Step (10), a material that makes the oxide semiconductor layer is indium gallium zinc oxides (IGZO).

The efficacy of the present invention is that the present invention provides a method for manufacturing a coplanar oxide semiconductor TFT substrate, which applies a half-tone process to carry out sectionized exposure and development on a photoresist layer, applying a stripping process to remove a remainder of the photoresist layer and a second metal layer deposited thereon so as to achieve forming a gate insulation layer and source/drain terminals with only one masking and one yellow light process. Compared to the conventional method for manufacturing a coplanar oxide semiconductor TFT substrate, the method for manufacturing a coplanar oxide semiconductor TFT substrate according to the present invention reduces the yellow light process, shortens workflow and production cycle of products, increases manufacturing efficiency and product yield rate, improves competition power of products, and reduces the number of masks needed so as to lower down the manufacturing cost.

### BRIEF DESCRIPTION OF THE DRAWINGS

To better understand the features and the technical contents of the present invention, reference is made to the following detailed description of embodiments of the present invention and drawings of the present invention. The drawings are provided for reference and illustration and are by no means to constrain the scope of the present invention. In the drawings:

FIG. 1 is a schematic view illustrating the first step of a method for manufacturing a conventional coplanar oxide semiconductor TFT substrate;

FIG. 2 is a schematic view illustrating the second step of the method for manufacturing the conventional coplanar oxide semiconductor TFT substrate;

FIG. 3 is a schematic view illustrating the third step of the method for manufacturing the conventional coplanar oxide semiconductor TFT substrate;

FIG. 4 is a schematic view illustrating the fourth step of the method for manufacturing the conventional coplanar oxide semiconductor TFT substrate;

FIG. 5 is a schematic view illustrating the fifth step of the method for manufacturing the conventional coplanar oxide semiconductor TFT substrate;

FIG. 6 is a flow chart illustrating a method for manufacturing a coplanar oxide semiconductor TFT substrate according to the present invention;

FIG. 7 is a schematic view illustrating the second step of the method for manufacturing the coplanar oxide semiconductor TFT substrate according to the present invention;

FIG. 8 is a schematic view illustrating the third step of the method for manufacturing the coplanar oxide semiconductor TFT substrate according to the present invention;

FIG. 9 is a schematic view illustrating the fourth step of the method for manufacturing the coplanar oxide semiconductor TFT substrate according to the present invention;

FIG. 10 is a schematic view illustrating the fifth step of the method for manufacturing the coplanar oxide semiconductor TFT substrate according to the present invention;

FIG. 11 is a schematic view illustrating the sixth step of the method for manufacturing the coplanar oxide semiconductor TFT substrate according to the present invention;

FIG. 12 is a schematic view illustrating the seventh step of the method for manufacturing the coplanar oxide semiconductor TFT substrate according to the present invention;

FIG. 13 is a schematic view illustrating the eighth step of the method for manufacturing the coplanar oxide semiconductor TFT substrate according to the present invention;

FIG. 14 is a schematic view illustrating the ninth step of the method for manufacturing the coplanar oxide semiconductor TFT substrate according to the present invention;

FIG. 15 is a schematic view illustrating the tenth step of the method for manufacturing the coplanar oxide semiconductor TFT substrate according to the present invention; and

FIG. 16 is a schematic view illustrating the eleventh step of the method for manufacturing the coplanar oxide semiconductor TFT substrate according to the present invention.

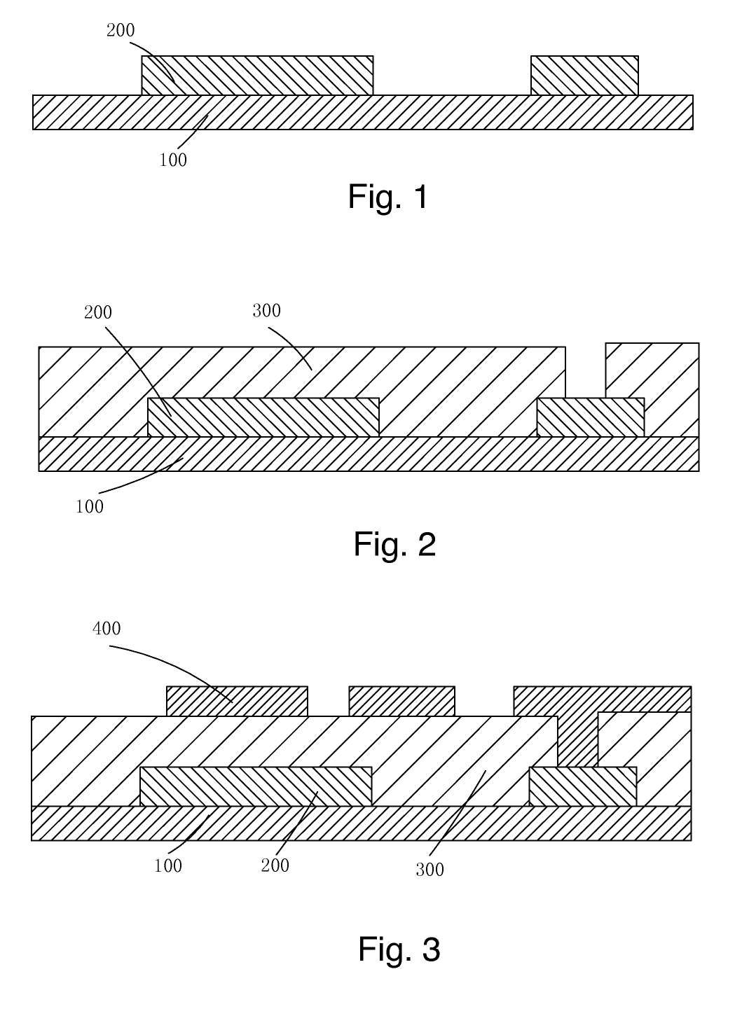

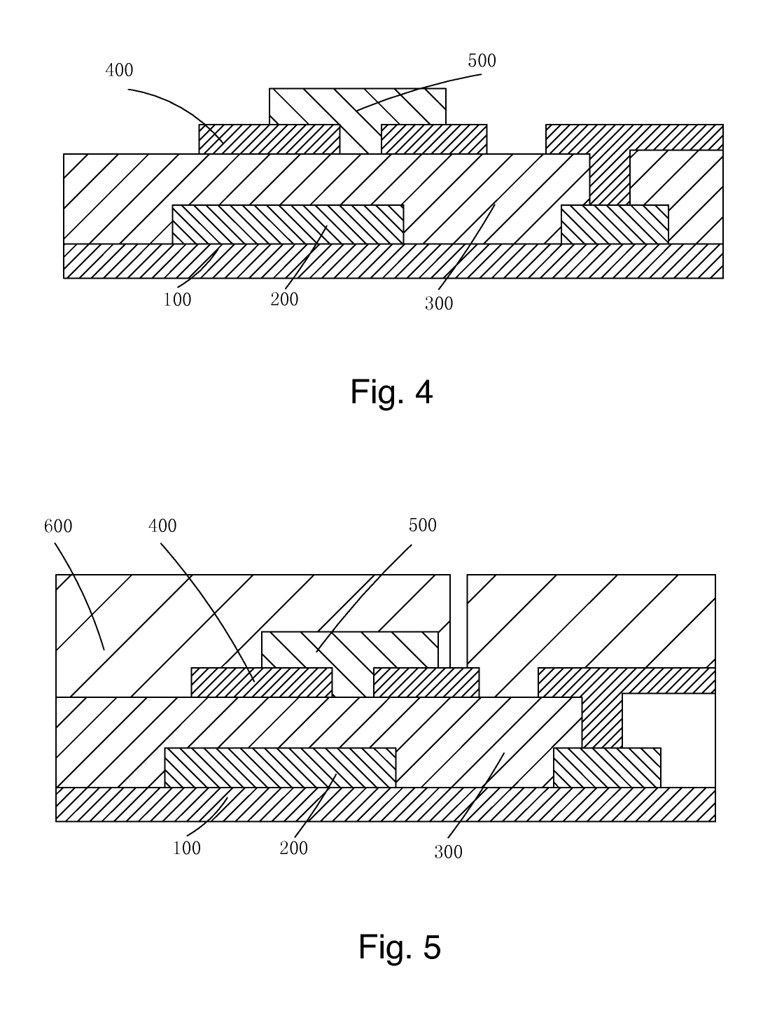

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

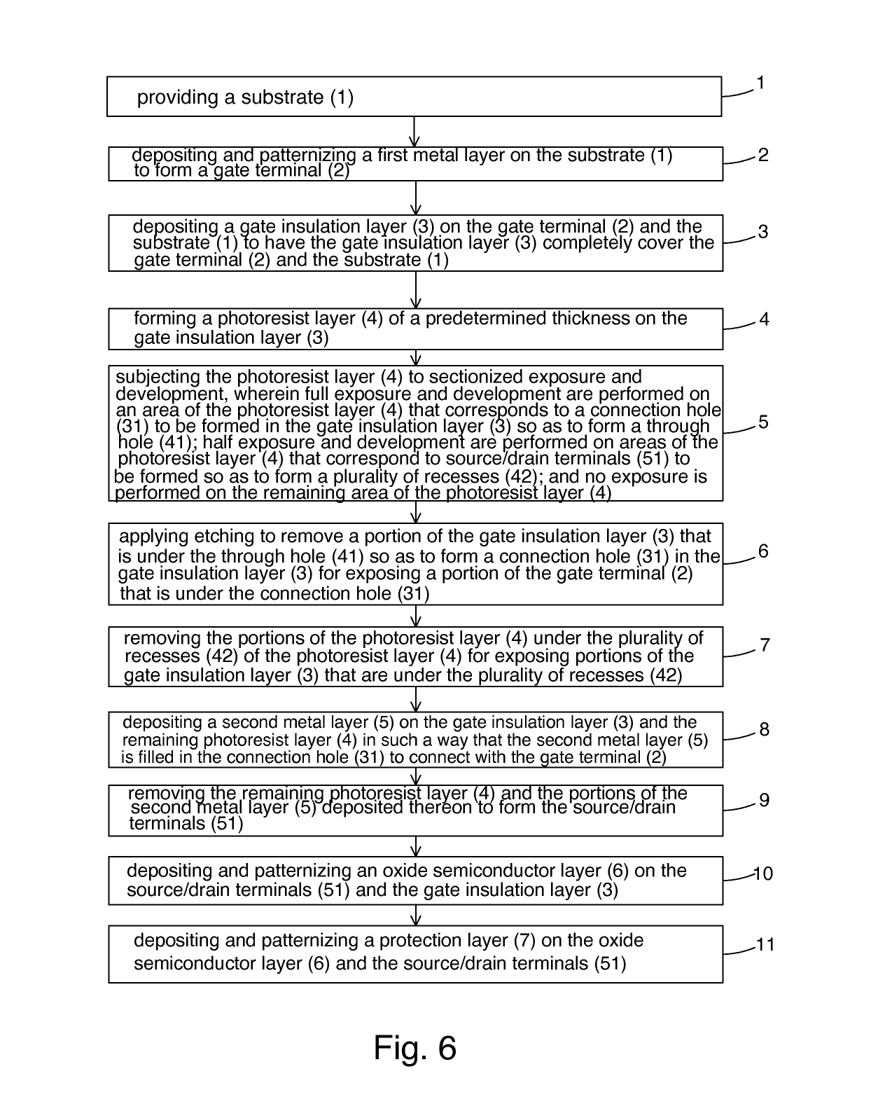

Referring to FIG. 6, which is a flow chart illustrating a method for manufacturing a coplanar oxide semiconductor TFT substrate according to the present invention, the method comprises the following steps:

Step 1: providing a substrate 1.

Specifically, the substrate 1 is a transparent substrate, and preferably, the substrate 1 is a glass substrate.

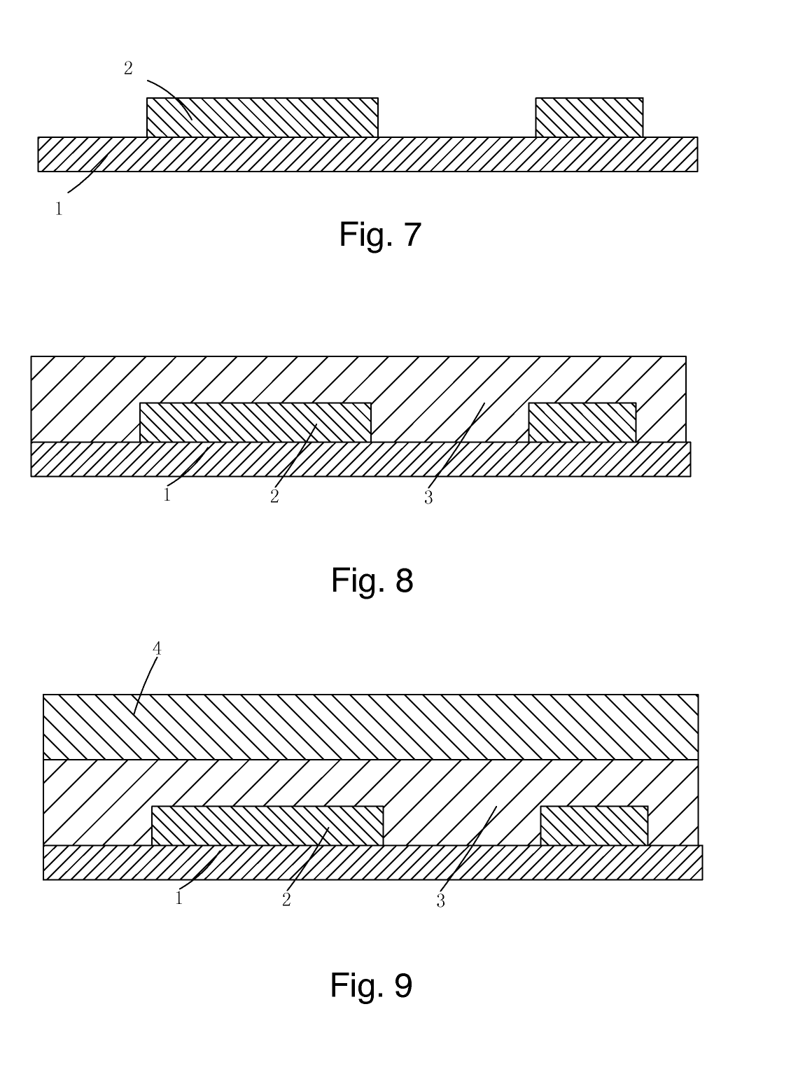

Step 2: referring to FIG. 7, depositing and patternizing a first metal layer on the substrate 1 to form a gate terminal 2.

Specifically, the patternizing operation is achieved with photolithography.

Step 3: referring to FIG. 8, depositing a gate insulation layer 3 on the gate terminal 2 and the substrate 1 to have the gate insulation layer 3 completely cover the gate terminal 2 and the substrate 1.

Step 4: referring to FIG. 9, forming a photoresist layer 4 of a predetermined thickness on the gate insulation layer 3.

Specifically, the photoresist layer 4 is formed by coating a photoresist. It is noted that to ensure a source/drain terminals 51 that is formed in a subsequent Step 9 to have a proper thickness, the photoresist layer 4 must be of a sufficient thickness.

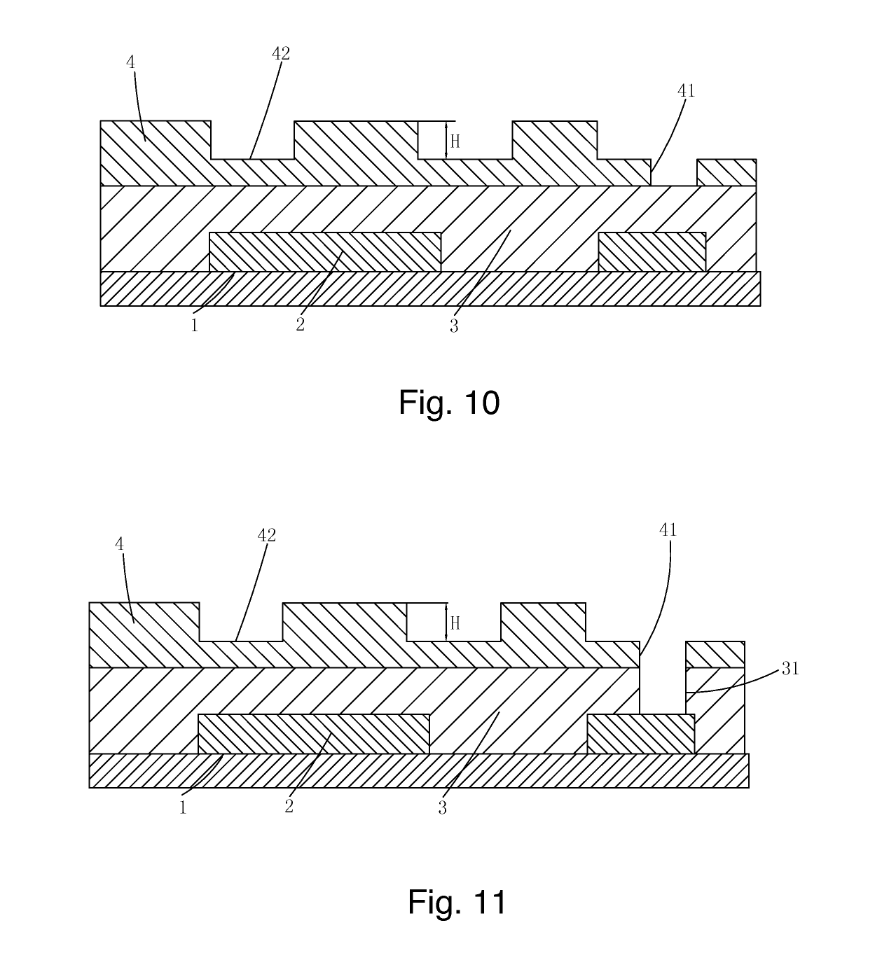

Step 5: referring to FIG. 10, subjecting the photoresist layer 4 to sectionized exposure and development.

Specifically, a half-tone process is employed to perform full exposure and development on an area of the photoresist layer 4 that corresponds to a connection hole 31 that will be formed in the gate insulation layer 3 so as to form a through hole 41; to perform half exposure and development on areas of the photoresist layer 4 that correspond to source/drain terminals 51 to be formed so as to form a plurality of recesses 42; and perform no exposure on the remaining area of the photoresist layer 4 to preserve the initial thickness of the photoresist layer 4, wherein the recesses 42 of the photoresist layer 4 have a depth H that is greater than the thickness of the source/drain terminals 51 to be formed.

Step 5 uses only one masking and one yellow light process to define the patterns to which the gate insulation layer 3 and the source/drain terminals 51 respectively correspond.

Step 6: referring to FIG. 11, applying dry etching to remove a portion of the gate insulation layer 3 that is under the through hole 41 so as to form a connection hole 31 in the gate insulation layer 3 for exposing a portion of the gate terminal 2 that is under the connection hole 31 thereby completing patternizing of the gate insulation layer 3.

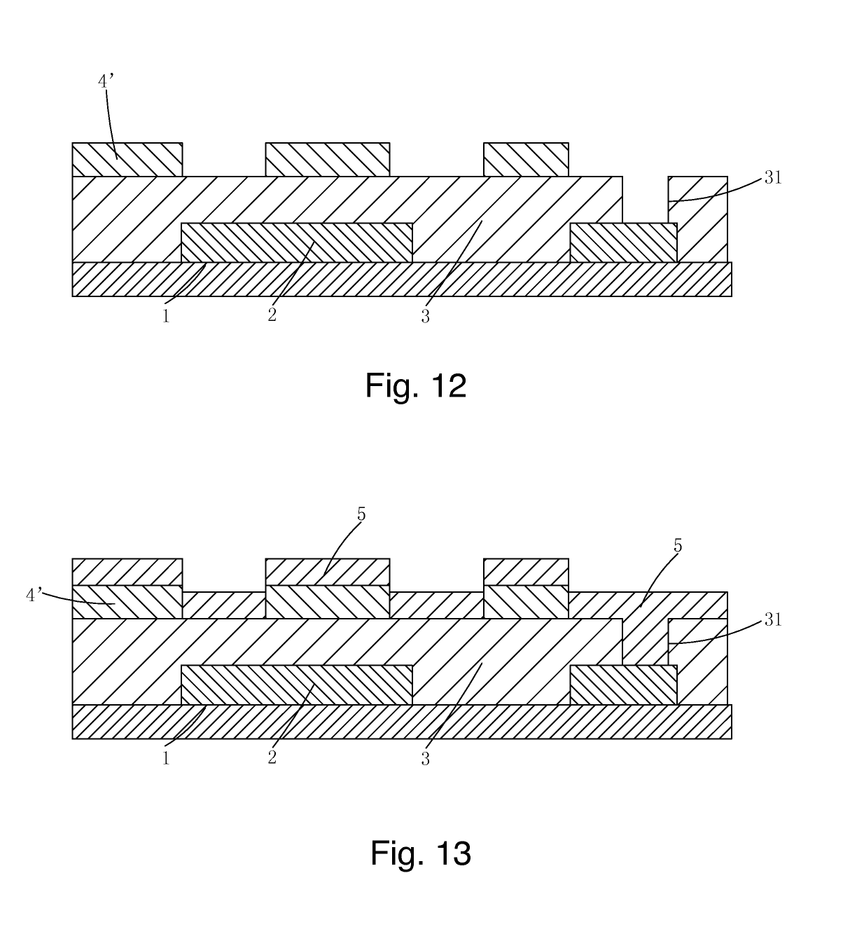

Step 7: referring to FIG. 12, applying O₂ ashing to remove the portions of the photoresist layer 4 under the plurality of recesses 42 of the photoresist layer 4 for exposing portions of the gate insulation layer 3 that are under the plurality of recesses 42.

Step 7 removes portions of the photoresist layer 4 that are under the plurality of recesses 42 of the photoresist layer 4 so that the source/drain terminals 51 formed in the subsequent Step 9 will be located on the exposed portions of the gate insulation layer 3. At the same time when the portions of the photoresist layer 4 that are located under the plurality of recesses 42 of the photoresist layer 4, a fraction of the thickness of a remaining portion of the photoresist layer 4 is also removed so that a remaining photoresist layer 4′ is of a thickness that is reduced.

Step 8: referring to FIG. 13, applying physical vapor deposition (PVD) to deposit a second metal layer 5 on the gate insulation layer 3 and the remaining photoresist layer 4′ in such a way that the second metal layer 5 is filled in the connection hole 31 to connect with the gate terminal 2.

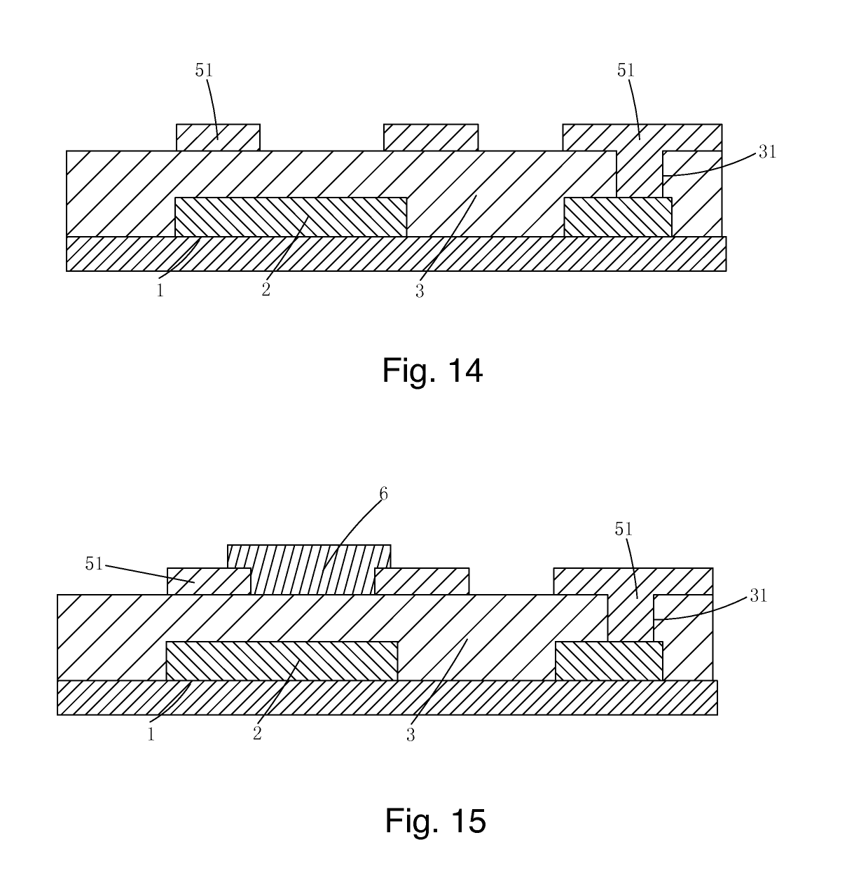

Step 9: referring to FIG. 14, removing the remaining photoresist layer 4′ and the portions of the second metal layer 5 deposited thereon to complete patternizing of the second metal layer 5 so as to form the source/drain terminals 51.

Specifically, in Step 9, a stripping solution is used to strip and remove the remaining photoresist layer 4′ and the portions of the second metal layer 5 deposited thereon. It is noted that since the stripping solution can dissolve the photoresist, but cannot dissolve metal so that the stripping solution may contain metal impurities thereon. A filter can be used to filter off the metal contained in the stripping solution in order to allow the stripping solution to be cyclically reused.

Step 10: referring to FIG. 15, depositing and patternizing an oxide semiconductor layer 6 on the source/drain terminals 51 and the gate insulation layer 3.

Specifically, a material that makes the oxide semiconductor layer 6 is indium gallium zinc oxides (IGZO).

The patternizing operation is achieved through photolithography.

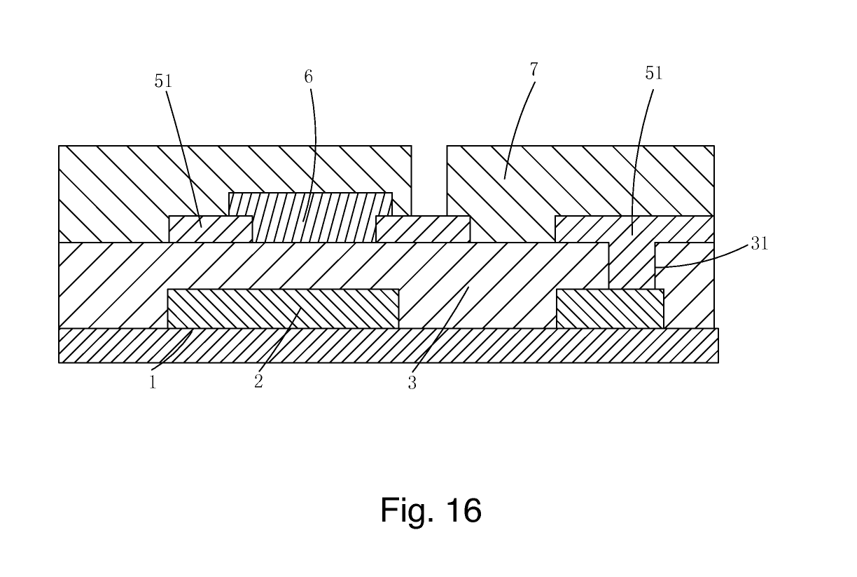

Step 11: referring to FIG. 16, depositing and patternizing a protection layer 7 on the oxide semiconductor layer 6 and the source/drain terminals 51 to complete the manufacture of a coplanar oxide semiconductor TFT substrate.

Specifically, the patternizing operation is achieved through photolithography.

The present invention provides a method for manufacturing a coplanar oxide semiconductor TFT substrate, which applies a half-tone process to carry out sectionized exposure and development on a photoresist layer, applying a stripping process to remove a remainder of the photoresist layer and a second metal layer deposited thereon so as to achieve forming a gate insulation layer and source/drain terminals with only one masking and one yellow light process. Compared to the conventional method for manufacturing a coplanar oxide semiconductor TFT substrate, the method for manufacturing a coplanar oxide semiconductor TFT substrate according to the present invention reduces the yellow light process, shortens workflow and production cycle of products, increases manufacturing efficiency and product yield rate, improves competition power of products, and reduces the number of masks needed so as to lower down the manufacturing cost.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing a coplanar oxide semiconductor TFT substrate, comprising the following steps:
(1) providing a substrate;
(2) depositing and patternizing a first metal layer on the substrate to form a gate terminal;
(3) depositing a gate insulation layer on the gate terminal and the substrate to have the gate insulation layer completely cover the gate terminal and the substrate;
(4) forming a photoresist layer of a predetermined thickness on the gate insulation layer;
(5) subjecting the photoresist layer to sectionized exposure and development;
wherein full exposure and development are performed on an area of the photoresist layer that corresponds to a connection hole to be formed in the gate insulation layer so as to form a through hole; half exposure and development are performed on areas of the photoresist layer that corresponds to source/drain terminals to be formed so as to form a plurality of recesses; and no exposure is performed on a remaining area of the photoresist layer;
(6) applying etching to remove a portion of the gate insulation layer that is under the through hole so as to form a connection hole in the gate insulation layer for exposing a portion of the gate terminal that is under the connection hole;
(7) removing portions of the photoresist layer that are under the plurality of recesses of the photoresist layer for exposing portions of the gate insulation layer that are under the plurality of recesses;
(8) depositing a second metal layer on the gate insulation layer and a remaining photoresist layer in such a way that the second metal layer is filled in the connection hole to connect with the gate terminal;
(9) removing the remaining photoresist layer and portions of the second metal layer deposited thereon so as to form source/drain terminals;
(10) depositing and patternizing an oxide semiconductor layer on the source/drain terminals and the gate insulation layer; and
(11) depositing and patternizing a protection layer on the oxide semiconductor layer and the source/drain terminals.

2. The method for manufacturing a coplanar oxide semiconductor TFT substrate as claimed in claim 1, wherein patternizing is achieved through photolithography.

3. The method for manufacturing a coplanar oxide semiconductor TFT substrate as claimed in claim 1, wherein in Step (5), a half-tone process is applied to perform the sectionized exposure of the photoresist layer.

4. The method for manufacturing a coplanar oxide semiconductor TFT substrate as claimed in claim 1, wherein in Step (5), the recesses of the photoresist layer have a depth H that is greater than a thickness of the source/drain terminals to be formed.

5. The method for manufacturing a coplanar oxide semiconductor TFT substrate as claimed in claim 1, wherein in Step (6), dry etching is applied to remove the portion of the gate insulation layer that is located under the through hole.

6. The method for manufacturing a coplanar oxide semiconductor TFT substrate as claimed in claim 1, wherein in Step (7), O₂ ashing is applied to remove the portions of the photoresist layer that are located under the plurality of recesses of the photoresist layer

7. The method for manufacturing a coplanar oxide semiconductor TFT substrate as claimed in claim 1, wherein in Step (8), physical vapor deposition is applied to deposit the second metal layer on the gate insulation layer and the remaining photoresist layer.

8. The method for manufacturing a coplanar oxide semiconductor TFT substrate as claimed in claim 1, wherein in Step (9), a stripping solution is applied to strip and remove the remaining photoresist layer and a portion of the second metal layer deposited thereon in order to form the source/drain terminals.

9. The method for manufacturing a coplanar oxide semiconductor TFT substrate as claimed in claim 1, wherein in Step (10), a material that makes the oxide semiconductor layer is indium gallium zinc oxides (IGZO).

10. A method for manufacturing a coplanar oxide semiconductor TFT substrate, comprising the following steps:
(1) providing a substrate;
(2) depositing and patternizing a first metal layer on the substrate to form a gate terminal;
(3) depositing a gate insulation layer on the gate terminal and the substrate to have the gate insulation layer completely cover the gate terminal and the substrate;
(4) forming a photoresist layer of a predetermined thickness on the gate insulation layer;
(5) subjecting the photoresist layer to sectionized exposure and development;
wherein full exposure and development are performed on an area of the photoresist layer that corresponds to a connection hole to be formed in the gate insulation layer so as to form a through hole; half exposure and development are performed on areas of the photoresist layer that corresponds to source/drain terminals to be formed so as to form a plurality of recesses; and no exposure is performed on a remaining area of the photoresist layer;
(6) applying etching to remove a portion of the gate insulation layer that is under the through hole so as to form a connection hole in the gate insulation layer for exposing a portion of the gate terminal that is under the connection hole;
(7) removing portions of the photoresist layer that are under the plurality of recesses of the photoresist layer for exposing portions of the gate insulation layer that are under the plurality of recesses;
(8) depositing a second metal layer on the gate insulation layer and a remaining photoresist layer in such a way that the second metal layer is filled in the connection hole to connect with the gate terminal;
(9) removing the remaining photoresist layer and portions of the second metal layer deposited thereon so as to form source/drain terminals;
(10) depositing and patternizing an oxide semiconductor layer on the source/drain terminals and the gate insulation layer; and
(11) depositing and patternizing a protection layer on the oxide semiconductor layer and the source/drain terminals;
wherein patternizing is achieved through photolithography;
wherein in Step (5), a half-tone process is applied to perform the sectionized exposure of the photoresist layer;
wherein in Step (5), the recesses of the photoresist layer have a depth H that is greater than a thickness of the source/drain terminals to be formed;
wherein in Step (6), dry etching is applied to remove the portion of the gate insulation layer that is located under the through hole;
wherein in Step (7), O₂ ashing is applied to remove the portions of the photoresist layer that are located under the plurality of recesses of the photoresist layer;
wherein in Step (8), physical vapor deposition is applied to deposit the second metal layer on the gate insulation layer and the remaining photoresist layer;
wherein in Step (9), a stripping solution is applied to strip and remove the remaining photoresist layer and a portion of the second metal layer deposited thereon in order to form the source/drain terminals; and
wherein in Step (10), a material that makes the oxide semiconductor layer is indium gallium zinc oxides (IGZO).
